(19) United States
(12) Patent Application Publication
(10) Pub. No.: US 2026/0262159 A1
(43) Pub. Date: Sep. 3, 2026

(54) MULTILAYER SUBSTRATE

(71) Applicant: Murata Manufacturing Co., Ltd., Nagaokakyo-shi (JP)

(72) Inventors: Taishi HOSOKAWA, Nagaokakyo-shi (JP); Iori AOYAMA, Nagaokakyo-shi (JP); Kenji MATSUDA, Nagaokakyo-shi (JP)

(21) Appl. No.: 19/653,320

(22) Filed: Apr. 21, 2026

Related U.S. Application Data
(63) Continuation of application No. PCT/JP2024/042097, filed on Nov. 28, 2024.

(30) Foreign Application Priority Data
Dec. 11, 2023 (JP) 2023-208799

(51) Int. Cl. H05K 1/02; H05K 1/11; H05K 1/181

(52) U.S. Cl. CPC H05K 1/0216; H05K 1/116; H05K 1/181; H05K 2201/0154; H05K 2201/09227; H05K 2201/10734

(57) ABSTRACT

In a multilayer substrate, a ground electrode overlaps an alternating current signal line in a thickness direction of a laminate substrate. The alternating current signal line includes signal lines spaced apart from each other in the thickness direction of the laminate substrate, and the signal lines are electrically connected by connection conductors penetrating insulating layers in the thickness direction of the laminate substrate. The signal lines include a first signal line adjacent to the ground electrode in the thickness direction of the laminate substrate and a second signal line adjacent to the first signal line in the thickness direction of the laminate substrate. A thickness of the first signal line is larger than a thickness of the second signal line in the thickness direction of the laminate substrate.

### CROSS REFERENCE TO RELATED APPLICATIONS

This application claims the benefit of priority to Japanese Patent Application No. 2023-208799 filed on Dec. 11, 2023 and is a Continuation Application of PCT Application No. PCT/JP2024/042097 filed on Nov. 28, 2024. The entire contents of each application are hereby incorporated herein by reference.

### BACKGROUND OF THE INVENTION

### 1. Field of the Invention

The present invention generally relates to multilayer substrates, and more particularly to multilayer substrates each including an alternating current signal line.

### 2. Description of the Related Art

International Publication No. WO 2023/037852 discloses a multilayer substrate including a multilayer body (laminate substrate) and three signal conductors (signal lines).

The multilayer body has a structure in which a plurality of resin layers (insulating layers) are laminated in a lamination direction. The positions of the three signal conductors (signal lines) in the lamination direction are different. The three signal conductors are electrically connected. In the multilayer substrate disclosed in International Publication No. WO 2023/037852, a high frequency signal is transmitted through the three signal conductors.

### SUMMARY OF THE INVENTION

In the multilayer substrate disclosed in International Publication No. WO 2023/037852, alternating current resistance becomes high in some cases.

Example embodiments of the present invention provide multilayer substrates that each enable reduction in alternating current resistance.

A multilayer substrate according to an example embodiment of the present invention includes a laminate substrate, an alternating current signal line, and a ground electrode. A plurality of insulating layers are laminated in the laminate substrate. The alternating current signal line is located in the laminate substrate. The ground electrode is located on or in the laminate substrate. The ground electrode overlaps the alternating current signal line in a thickness direction of the laminate substrate. The alternating current signal line includes a plurality of signal lines spaced apart from each other in the thickness direction of the laminate substrate. In the alternating current signal line, the plurality of signal lines are electrically connected by a plurality of connection conductors penetrating one of the plurality of insulating layers in the thickness direction of the laminate substrate. The plurality of signal lines include a first signal line adjacent to the ground electrode in the thickness direction of the laminate substrate and a second signal line adjacent to the first signal line in the thickness direction of the laminate substrate. A thickness of the first signal line is larger than a thickness of the second signal line in the thickness direction of the laminate substrate.

Multilayer substrates according to example embodiments of the present invention enable reduction in alternating current resistance.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a plan view of a portion of a multilayer substrate according to example embodiment 1 of the present invention.

FIG. 2 relates to the multilayer substrate according to example embodiment 1, and is a cross-sectional view taken along line II-II in FIG. 1.

FIG. 3 relates to the multilayer substrate according to example embodiment 1, and is a cross-sectional view taken along line III-III in FIG. 1.

FIG. 4 is a cross-sectional view of a multilayer substrate according to example embodiment 2 of the present invention.

FIG. 5 is a cross-sectional view of a multilayer substrate according to example embodiment 3 of the present invention.

FIG. 6 is a cross-sectional view of a multilayer substrate according to example embodiment 4 of the present invention.

FIG. 7 is a plan view of a portion of a multilayer substrate according to example embodiment 5 of the present invention.

FIG. 8 is a plan view depicting, in a see-through manner, a first signal line, a fourth ground electrode, and an RF signal line in part of the multilayer substrate according to example embodiment 5.

FIG. 9 relates to the multilayer substrate according to example embodiment 5, and is a cross-sectional view taken along line IX-IX in FIG. 7.

FIG. 10 is a cross-sectional view of a multilayer substrate according to example embodiment 6 of the present invention.

FIG. 11 is a cross-sectional view of a multilayer substrate according to example embodiment 7 of the present invention.

FIG. 12 is a cross-sectional view of a multilayer substrate according to example embodiment 8 of the present invention.

FIG. 13 is a cross-sectional view of a multilayer substrate according to example embodiment 9 of the present invention.

FIG. 14 is a cross-sectional view of a multilayer substrate according to example embodiment 10 of the present invention.

FIG. 15 is a cross-sectional view of a multilayer substrate according to example embodiment 11 of the present invention.

FIG. 16 is a cross-sectional view of a multilayer substrate according to example embodiment 12 of the present invention.

FIG. 17 is a cross-sectional view of a portion of a multilayer substrate according to example embodiment 13 of the present invention.

### DETAILED DESCRIPTION OF THE EXAMPLE EMBODIMENTS

Example embodiments 1 to 13 and the like are described below with reference to the drawings. The drawings referred to in the following example embodiments 1 to 13 and the like are schematic diagrams, and sizes and thicknesses of components in the drawings do not necessarily reflect actual dimensions. Further, the ratios of sizes and the ratios of thicknesses among the components also do not necessarily reflect actual dimensional ratios.

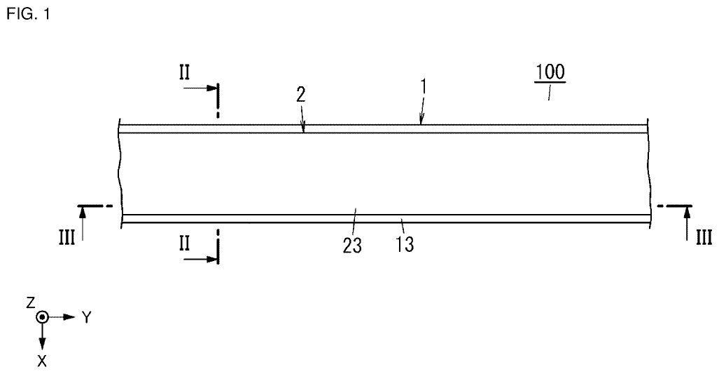

A multilayer substrate 100 according to example embodiment 1 is described with reference to FIGS. 1 to 3.

As depicted in FIGS. 1 to 3, the multilayer substrate 100 according to example embodiment 1 includes a laminate substrate 1, an alternating current signal line 2, and a ground electrode 4.

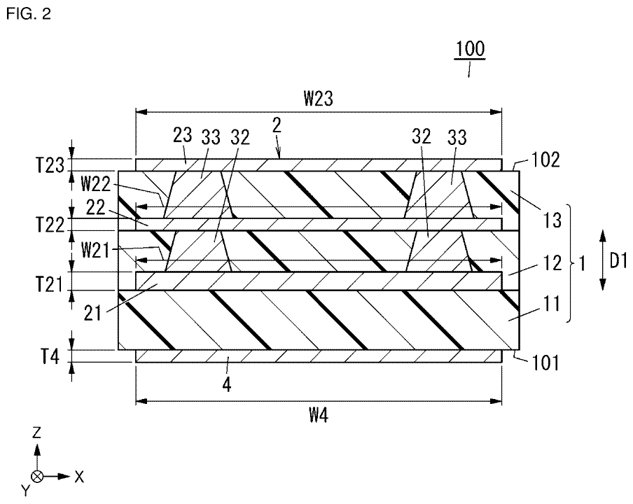

In each of FIGS. 1 to 3, a Cartesian coordinate system having three axes of an X-axis, a Y-axis, and a Z-axis orthogonal to each other is defined, and an axis along a thickness direction D1 (see FIG. 2) of the laminate substrate 1 is indicated as the Z-axis. The X-axis, the Y-axis, and the Z-axis are all virtual axes. Arrows indicating “X,” “Y,” and “Z” in the drawings are merely depicted for description, and none of them is associated with a physical entity. The multilayer substrate 100 is, for example, a flexible substrate. In the example of FIG. 1, the thickness direction D1 of the multilayer substrate 100 is a direction along the Z-axis. However, when the multilayer substrate 100 is bent, the thickness direction D1 differs depending on a position of the multilayer substrate 100.

The multilayer substrate 100 is, for example, housed in a housing of electronic equipment. The electronic equipment is, for example, a communication device. The communication device is, for example, a cellular phone (for example, smartphone), but is not limited to a cellular phone, and may be, for example, a notebook personal computer, a wearable terminal (for example, smartwatch), or the like.

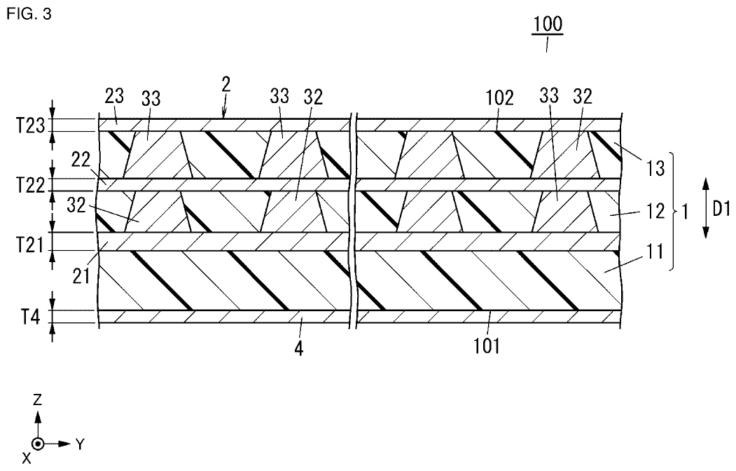

As depicted in FIGS. 2 and 3, the laminate substrate 1 includes a plurality of (three, in the example of FIGS. 2 and 3) insulating layers 11, 12, and 13, and the insulating layers 11, 12, and 13 are laminated. The thickness direction D1 of the laminate substrate 1 is a lamination direction of the insulating layers 11, 12, and 13. Hereinafter, for convenience of description, the insulating layer 11, the insulating layer 12, and the insulating layer 13 are sometimes referred to as the first insulating layer 11, the second insulating layer 12, and the third insulating layer 13, respectively.

In the laminate substrate 1, the first insulating layer 11, the second insulating layer 12, and the third insulating layer 13 are laminated in order of the first insulating layer 11, the second insulating layer 12, and the third insulating layer 13.

A material of each of the insulating layers 11, 12, and 13 includes, for example, a thermoplastic resin. The thermoplastic resin is, for example, a liquid crystal polymer. The thermoplastic resin is not limited to a liquid crystal polymer, and may be, for example, polytetrafluoroethylene (PTFE). In the present example embodiment, the first insulating layer 11 and the second insulating layer 12 are made to self-adhere to each other, and an adhesive layer is not interposed between the first insulating layer 11 and the second insulating layer 12. Further, in the present example embodiment, the second insulating layer 12 and the third insulating layer 13 are made to self-adhere to each other, and an adhesive layer is not interposed between the second insulating layer 12 and the third insulating layer 13.

A thickness of each of the insulating layers 11, 12, and 13 is, for example, about 10 μm or more and about 120 μm or less.

In the present example embodiment, in plan view from the thickness direction D1 of the laminate substrate 1, the laminate substrate 1 has an elongated shape in which a length in a direction along the Y-axis is longer than a length in a direction along the X-axis. The laminate substrate 1 may have a shape other than the elongated shape in plan view from the thickness direction D1 of the laminate substrate 1.

As depicted in FIG. 1, the alternating current signal line 2 is included in the laminate substrate 1. The alternating current signal line 2 is a line through which a signal is transmitted. In the present disclosure, the alternating current signal line 2 is a line through which a signal whose magnitude changes with time is transmitted. The alternating current signal line 2 is, for example, a near field communication (NFC) signal line. In the present example embodiment, a signal transmitted through the alternating current signal line 2 is, for example, an alternating current signal having a frequency of 13.56 MHz.

As depicted in FIGS. 2 and 3, the alternating current signal line 2 includes a plurality of signal lines (signal electrodes) 21, 22, and 23 spaced apart from each other in the thickness direction D1 of the laminate substrate 1. The signal lines 21, 22, and 23 overlap each other in plan view from the thickness direction D1 of the laminate substrate 1.

Each of the signal lines 21 to 23 has conductivity. A material of each of the signal lines 21 to 23 includes, for example, copper.

The signal line 21 is laminated on the first insulating layer 11. The signal line 22 is laminated on the second insulating layer 12. The signal line 23 is laminated on the third insulating layer 13. In the multilayer substrate 100, the ground electrode 4, the first insulating layer 11, the signal line 21, the second insulating layer 12, the signal line 22, the third insulating layer 13, and the signal line 23 are laminated in order of the ground electrode 4, the first insulating layer 11, the signal line 21, the second insulating layer 12, the signal line 22, the third insulating layer 13, and the signal line 23. Hereinafter, for convenience of description, the signal line 21 and the signal line 22 are sometimes referred to as the first signal line 21 and the second signal line 22, respectively. The signal lines 21 to 23 include the first signal line 21 adjacent to the ground electrode 4 in the thickness direction D1 of the laminate substrate 1 and the second signal line 22 adjacent to the first signal line 21 in the thickness direction D1 of the laminate substrate 1.

Each of the signal lines 21 to 23 is arranged in a predetermined pattern. In the present example embodiment, each of the signal lines 21 to 23 has a linear shape in plan view from the thickness direction D1 of the laminate substrate 1. Each of the signal lines 21 to 23 may have a shape different from the linear shape in plan view from the thickness direction D1 of the laminate substrate 1. The first signal line 21 is formed, for example, by patterning a copper foil (hereinafter, also referred to as a first copper foil) applied to the first insulating layer 11. The second signal line 22 is formed, for example, by patterning a copper foil (hereinafter, also referred to as a second copper foil) applied to the second insulating layer 12. The signal line 23 is formed, for example, by patterning a copper foil (hereinafter, also referred to as a third copper foil) applied to the third insulating layer 13. The ground electrode 4 is formed, for example, by patterning a copper foil (hereinafter, also referred to as a fourth copper foil) applied to a second main surface on a side opposite to a first main surface that is a main surface of the first insulating layer 11 to which the first copper foil is applied. A multilayer body including the ground electrode 4, the first insulating layer 11, and the first signal line 21 may be formed by laminating two single-sided copper-clad films.

The signal lines 21, 22, and 23 have line widths W21, W22, and W23, respectively. In the present example embodiment, the line width W21 of the first signal line 21, the line width W22 of the second signal line 22, and the line width W23 of the signal line 23 are the same. In the multilayer substrate 100, it is preferable that the line widths W21 to W23 be the same as each other and be larger in terms of increasing the cross-sectional area of the alternating current signal line 2. However, the line widths W21 to W23 may be different from each other. The “cross-sectional area of the alternating current signal line 2” is the total cross-sectional area that is the sum of the cross-sectional areas of the respective signal lines 21 to 23 in any one cross section orthogonal to a length direction of the alternating current signal line 2.

A thickness of each of the signal lines 21 to 23 is smaller than the thickness of each of the insulating layers 11 to 13. Thicknesses T21, T22, and T23 of the signal lines 21, 22, and 23, respectively, are described in a section “(2) Thickness of Each of Signal Lines and Thickness of Ground Electrode.”

Further, the alternating current signal line 2 includes a plurality of connection conductors that electrically connect the signal lines 21 to 23. Each of the connection conductors is an interlayer connection conductor that connects the signal lines located on two insulating layers different from each other among the insulating layers 11 to 13. Each of the connection conductors has conductivity. In the alternating current signal line 2, the signal lines 21 to 23 are electrically connected by the connection conductors penetrating one of the insulating layers 11 to 13 in the thickness direction D1 of the laminate substrate 1. The connection conductors include a plurality of first connection conductors 32 penetrating the second insulating layer 12 and a plurality of second connection conductors 33 penetrating the third insulating layer 13.

In the present example embodiment, the first connection conductors 32 and the second connection conductors 33 correspond to each other on a one-to-one basis, and the first connection conductor 32 and the second connection conductor 33 corresponding to each other overlap in the thickness direction D1 of the laminate substrate 1. In the alternating current signal line 2, the first connection conductor 32 and the second connection conductor 33 may be shifted from each other in a direction in which a signal is transmitted (the Y-axis direction, in the example of FIGS. 2 and 3).

In the present example embodiment, the first connection conductors 32 are interposed between the first signal line 21 and the second signal line 22 in the thickness direction D1 of the laminate substrate 1. The first connection conductors 32 are arranged in two rows, and the first connection conductors 32 in each row are spaced apart from each other in a length direction of the second signal line 22. The length direction of the second signal line 22 is a direction along the second signal line 22, and is a direction orthogonal to a width direction (line width direction) of the second signal line 22, and is a direction in which a signal is transmitted in the second signal line 22.

Further, the second connection conductors 33 are interposed between the second signal line 22 and the signal line 23 in the thickness direction D1 of the laminate substrate 1. The second connection conductors 33 are arranged in two rows, and the second connection conductors 33 in each row are spaced apart from each other in a length direction of the signal line 23. The length direction of the signal line 23 is a direction along the signal line 23, and is a direction orthogonal to a width direction (line width direction) of the signal line 23, and is a direction in which a signal is transmitted in the signal line 23. In the present example embodiment, the first signal line 21 and the second signal line 22 are electrically connected by the first connection conductors 32, and the second signal line 22 and the signal line 23 are electrically connected by the second connection conductors 33.

Each of the first connection conductors 32 and the second connection conductors 33 has conductivity. Each of the first connection conductors 32 and the second connection conductors 33 includes, for example, copper, a copper-tin alloy, and a resin. The first connection conductors 32 are formed, for example, by filling a plurality of via-holes formed in the second insulating layer 12 with a conductive paste including copper, a low-melting-point metal (for example, tin), and a resin and heating the conductive paste in a state in which each of the via-holes is closed by part of the second copper foil. The second connection conductors 33 are formed, for example, by filling a plurality of via-holes formed in the third insulating layer 13 with a conductive paste including copper, a low-melting-point metal (for example, tin), and a resin and heating the conductive paste in a state in which each of the via-holes is closed by a portion of the third copper foil.

As depicted in FIGS. 2 and 3, the ground electrode 4 is located on the laminate substrate 1. The ground electrode 4 overlaps the signal lines 21 to 23 in plan view from the thickness direction D1 of the laminate substrate 1.

The ground electrode 4 is adjacent to the first signal line 21 among the signal lines 21 to 23 in the thickness direction D1 of the laminate substrate 1. The expression “the ground electrode 4 is adjacent to the first signal line 21 among the signal lines 21 to 23 in the thickness direction D1 of the laminate substrate 1” means that the ground electrode 4 and the first signal line 21 are spaced apart from each other without the other signal lines 22 and 23 being disposed between the ground electrode 4 and the first signal line 21 in the thickness direction of the laminate substrate 1.

The ground electrode 4 is laminated on a surface of the first insulating layer 11 on a side opposite to a surface on which the first signal line 21 is laminated. The ground electrode 4 is located on a main surface 101 (hereinafter, also referred to as the first main surface 101) of the laminate substrate 1. The first main surface 101 of the laminate substrate 1 is a main surface on a side opposite to a second main surface 102 of the laminate substrate 1 on which the signal line 23 is laminated.

The ground electrode 4 has conductivity. A material of the ground electrode 4 includes, for example, copper.

The ground electrode 4 is located in a predetermined pattern. In the present example embodiment, the ground electrode 4 has a linear shape in plan view from the thickness direction D1 of the laminate substrate 1. The ground electrode 4 may have a shape different from the linear shape in plan view from the thickness direction D1 of the laminate substrate 1.

In the present example embodiment, the ground electrode 4 is formed, for example, by patterning the fourth copper foil applied to the first insulating layer 11. A width W4 of the ground electrode 4 is the same as the line width W21 of the first signal line 21 in a width direction of the first signal line 21.

The thickness of each of the signal lines 21 to 23 is, for example, about 3 μm or more and about 40 μm or less. In the present example embodiment, in terms of reducing unevenness of current density of the alternating current signal line 2 in the width direction due to a proximity effect and reducing alternating current resistance, the thickness T21 of the first signal line 21 is preferably larger than the thickness T22 of the second signal line 22 and smaller than or equal to five times the thickness T22. More preferably, the thickness T21 of the first signal line 21 is larger than the thickness T22 of the second signal line 22 and smaller than or equal to two times the thickness T22.

In the present example embodiment, as an example, the thickness T21 of the first signal line 21, the thickness T22 of the second signal line 22, and the thickness T23 of the signal line 23 are about 18 μm, about 12 μm, and about 12 μm, respectively. In the present example embodiment, the thickness T23 of the signal line 23 is the same as the thickness T22 of the second signal line 22, but may be different from the thickness T22 of the second signal line 22.

In the present example embodiment, a thickness T4 of the ground electrode 4 is smaller than the thickness T21 of the first signal line 21. In the present example embodiment, the thickness T4 of the ground electrode 4 is, for example, the same as the thickness T22 of the second signal line 22, but may be different from the thickness T22 of the second signal line 22.

The multilayer substrate 100 of the present example embodiment can reduce the alternating current resistance of the alternating current signal line 2 while suppressing an increase in the overall thickness of the multilayer substrate 100, compared with a multilayer substrate including an alternating current signal line including a plurality of signal lines having the same thickness as each other.

In the multilayer substrate 100 of the present example embodiment, for example, when the thickness T21 of the first signal line 21, the thickness T22 of the second signal line 22, and the thickness T23 of the signal line 23 are set to about 18 μm, about 12 μm, and about 12 μm, respectively, the alternating current resistance can be reduced compared with a multilayer substrate including an alternating current signal line including a plurality of signal lines each having a thickness of about 14 μm, for example.

In a manufacturing method for the multilayer substrate 100 of the present example embodiment, for example, the following single-sided copper-clad films are disposed over a metal plate (not depicted) in a stacked manner: a single-sided copper-clad film on which the ground electrode 4 is formed; a single-sided copper-clad film on which the first signal line 21 is formed; a single-sided copper-clad film in which each of a plurality of via-holes closed by the second signal line 22 pattern-formed on one surface of the second insulating layer 12 is filled with a conductive paste; and a single-sided copper-clad film in which each of a plurality of via-holes closed by the signal line 23 pattern-formed on one surface of the third insulating layer 13 is filled with a conductive paste. Then, these films are pressed from above while being heated, and thereby the multilayer substrate 100 is formed.

In the multilayer substrate 100 according to example embodiment 1, the ground electrode 4 overlaps the alternating current signal line 2 in the thickness direction D1 of the laminate substrate 1. The alternating current signal line 2 has the signal lines 21 to 23 spaced apart from each other in the thickness direction D1 of the laminate substrate 1, and the signal lines 21 to 23 are electrically connected by the connection conductors penetrating one of the insulating layers 11 to 13 in the thickness direction D1 of the laminate substrate 1. The signal lines 21 to 23 include the first signal line 21 adjacent to the ground electrode 4 in the thickness direction D1 of the laminate substrate 1 and the second signal line 22 adjacent to the first signal line 21 in the thickness direction D1 of the laminate substrate 1. The thickness T21 of the first signal line 21 is larger than the thickness T22 of the second signal line 22 in the thickness direction D1 of the laminate substrate 1.

With the above configuration, the alternating current resistance of the multilayer substrate 100 can be reduced. Specifically, the multilayer substrate 100 according to example embodiment 1 can reduce unevenness of the current distribution in the width direction in the first signal line 21 adjacent to the ground electrode 4 in the thickness direction D1 of the laminate substrate 1 among the signal lines 21 to 23 spaced apart from each other in the thickness direction D1 of the laminate substrate 1, and can improve the current distribution of the first signal line 21 (can achieve uniformity of the current distribution of the first signal line 21). Thus, with the above configuration, a current can be caused to flow more efficiently by increasing the thickness of the first signal line 21 whose current distribution can be improved. Accordingly, it is possible to reduce the alternating current resistance of the alternating current signal line 2 while suppressing an increase in the overall thickness of the multilayer substrate 100.

Further, in the multilayer substrate 100 according to example embodiment 1, the ground electrode 4 overlaps the entire region of the first signal line 21 in the width direction in the thickness direction D1 of the laminate substrate 1.

With the above configuration, noise resistance can be improved.

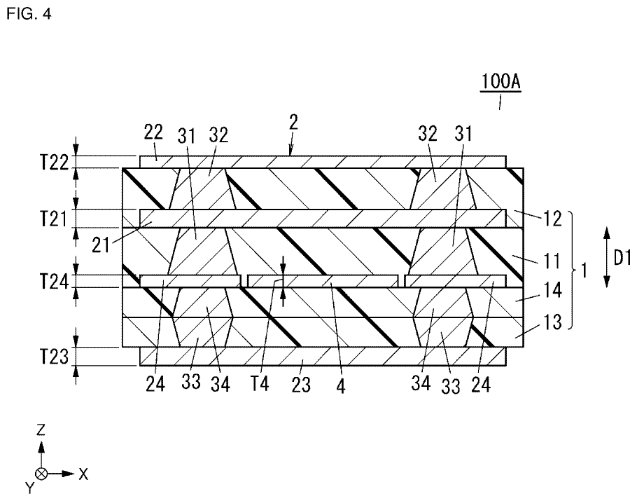

A multilayer substrate 100A according to example embodiment 2 is described with reference to FIG. 4. For the multilayer substrate 100A according to example embodiment 2, components similar to those of the multilayer substrate 100 according to example embodiment 1 (see FIGS. 1 to 3) are given the same reference numerals, and description thereof is omitted. In FIG. 4, similarly to FIGS. 1 to 3, a Cartesian coordinate system having three axes of an X-axis, a Y-axis, and a Z-axis orthogonal to each other is defined and indicated.

The multilayer substrate 100A according to example embodiment 2 is different from the multilayer substrate 100 according to example embodiment 1 in that the multilayer substrate 100A further includes an insulating layer 14 (hereinafter, also referred to as the fourth insulating layer 14). In the present example embodiment, the fourth insulating layer 14 is located between the third insulating layer 13 and the first insulating layer 11 in the thickness direction D1 of the laminate substrate 1. A material of the fourth insulating layer 14 is the same as the material of the first insulating layer 11, the second insulating layer 12, and the third insulating layer 13. Further, in the multilayer substrate 100A according to example embodiment 2, the alternating current signal line 2 further includes two signal lines 24 (hereinafter, also referred to as the third signal lines 24) adjacent to the ground electrode 4 in the width direction of the first signal line 21. In the thickness direction D1 of the laminate substrate 1, the two third signal lines 24 overlap the first signal line 21 and are spaced apart from the first signal line 21. The two third signal lines 24 are formed on a main surface of the fourth insulating layer 14 on the first insulating layer 11 side. A material of the two third signal lines 24 is the same as the material of the ground electrode 4. In the multilayer substrate 100A according to example embodiment 2, as depicted in FIG. 4, in the thickness direction D1 of the laminate substrate 1, the signal line 23, the third insulating layer 13, the fourth insulating layer 14, the ground electrode 4, the first insulating layer 11, the first signal line 21, the second insulating layer 12, and the second signal line 22 are arranged in order of the signal line 23, the third insulating layer 13, the fourth insulating layer 14, the ground electrode 4, the first insulating layer 11, the first signal line 21, the second insulating layer 12, and the second signal line 22. Further, in the multilayer substrate 100A, in the thickness direction D1 of the laminate substrate 1, the signal line 23, the third insulating layer 13, the fourth insulating layer 14, the third signal line 24, the first insulating layer 11, the first signal line 21, the second insulating layer 12, and the second signal line 22 are arranged in order of the signal line 23, the third insulating layer 13, the fourth insulating layer 14, the third signal line 24, the first insulating layer 11, the first signal line 21, the second insulating layer 12, and the second signal line 22.

In example embodiment 2, a plurality of connection conductors that electrically connect the signal lines 21 to 24 in the alternating current signal line 2 include a plurality of first connection conductors 32 penetrating the second insulating layer 12, a plurality of second connection conductors 33 penetrating the third insulating layer 13, a plurality of third connection conductors 31 penetrating the first insulating layer 11, and a plurality of fourth connection conductors 34 penetrating the fourth insulating layer 14.

In the present example embodiment, the second connection conductors 33 and the fourth connection conductors 34 correspond to each other on a one-to-one basis, and the second connection conductor 33 and the fourth connection conductor 34 corresponding to each other overlap in the thickness direction D1 of the laminate substrate 1. Further, in the present example embodiment, the first connection conductor 32, the third connection conductor 31, and the second connection conductor 33 overlap each other in the thickness direction D1 of the laminate substrate 1. However, the first connection conductor 32, the third connection conductor 31, and the second connection conductor 33 may be disposed so as to be shifted from each other in a direction in which a signal is transmitted (the Y-axis direction, in the example of FIG. 4).

In the present example embodiment, the first connection conductors 32 are interposed between the first signal line 21 and the second signal line 22 in the thickness direction D1 of the laminate substrate 1. The first connection conductors 32 are arranged in two rows, and the first connection conductors 32 in each row are spaced apart from each other in the length direction of the second signal line 22. The length direction of the second signal line 22 is the direction along the second signal line 22, and is the direction orthogonal to the width direction (line width direction) of the second signal line 22, and is the direction in which a signal is transmitted in the second signal line 22.

Further, in the multilayer substrate 100A, the third connection conductors 31 are interposed between the first signal line 21 and the two signal lines 24 in the thickness direction D1 of the laminate substrate 1. The third connection conductors 31 are arranged in two rows, and the third connection conductors 31 in each row are spaced apart from each other in a length direction of the first signal line 21. The length direction of the first signal line 21 is a direction along the first signal line 21, and is a direction orthogonal to the width direction (line width direction) of the first signal line 21, and is a direction in which a signal is transmitted in the first signal line 21. Further, in the multilayer substrate 100A, the fourth connection conductors 34 connected to the signal line 24 and the second connection conductors 33 corresponding to the fourth connection conductors 34 on a one-to-one basis are interposed between the signal line 24 and the signal line 23 in the thickness direction D1 of the laminate substrate 1. The fourth connection conductors 34 are arranged in two rows, and the fourth connection conductors 34 in each row are spaced apart from each other in a length direction of the signal line 24. The length direction of the signal line 24 is a direction along the signal line 24, and is a direction orthogonal to a width direction (line width direction) of the signal line 24, and is a direction in which a signal is transmitted in the signal line 24. The second connection conductors 33 are arranged in two rows, and the second connection conductors 33 in each row are spaced apart from each other in the length direction of the signal line 23. The length direction of the signal line 23 is the direction along the signal line 23, and is the direction orthogonal to the width direction (line width direction) of the signal line 23, and is the direction in which a signal is transmitted in the signal line 23. In the present example embodiment, the first signal line 21 and the second signal line 22 are electrically connected by the first connection conductors 32. Further, in the present example embodiment, the first signal line 21 and the two signal lines 24 are electrically connected by the third connection conductors 31. Further, in the present example embodiment, the two signal lines 24 and the signal line 23 are electrically connected by the fourth connection conductors 34 and the second connection conductors 33.

In example embodiment 2, the thickness T23 of the signal line 23 is larger than the thickness T22 of the second signal line 22 and the thickness T24 of the signal line 24 in the thickness direction D1 of the laminate substrate 1. In example embodiment 2, as an example, the thickness T21 of the first signal line 21, the thickness T22 of the second signal line 22, the thickness T23 of the signal line 23, and the thickness T24 of the signal line 24 are about 18 μm, about 12 μm, about 18 μm, and about 12 μm, respectively. In example embodiment 2, the thickness T23 of the signal line 23 is the same as the thickness T21 of the first signal line 21, but may be different from the thickness T21 of the first signal line 21.

In the multilayer substrate 100A according to example embodiment 2, the alternating current resistance can be further reduced because each of the thickness T21 of the first signal line 21 and the thickness T23 of the signal line 23 is larger than the thickness T22 of the second signal line 22 in the thickness direction D1 of the laminate substrate 1.

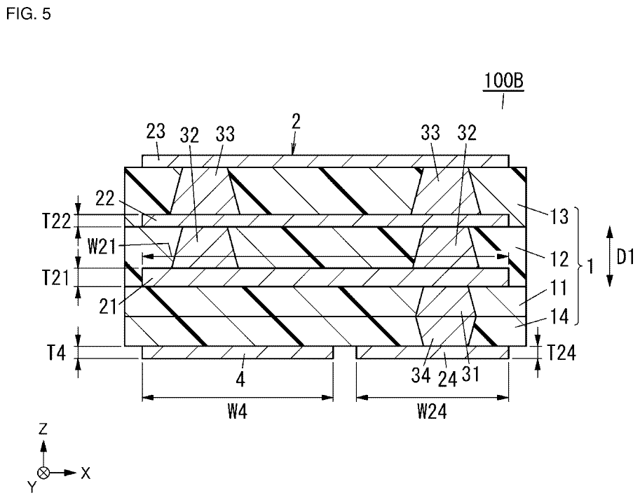

A multilayer substrate 100B according to example embodiment 3 is described with reference to FIG. 5. For the multilayer substrate 100B according to example embodiment 3, components similar to those of the multilayer substrate 100 according to example embodiment 1 (see FIGS. 1 to 3) are given the same reference numerals, and description thereof is omitted. In FIG. 5, similarly to FIGS. 1 to 3, a Cartesian coordinate system having three axes of an X-axis, a Y-axis, and a Z-axis orthogonal to each other is defined, and an axis along the thickness direction D1 of the laminate substrate 1 is indicated as the Z-axis.

The multilayer substrate 100B according to example embodiment 3 is different from the multilayer substrate 100 according to example embodiment 1 in that the multilayer substrate 100B further includes the insulating layer 14 (hereinafter, also referred to as the fourth insulating layer 14). In the present example embodiment, the fourth insulating layer 14 is located adjacent to the first insulating layer 11 on a side opposite to the second insulating layer 12 side in the thickness direction D1 of the laminate substrate 1. The material of the fourth insulating layer 14 is the same as the material of the first insulating layer 11, the second insulating layer 12, and the third insulating layer 13. Further, in the multilayer substrate 100B according to example embodiment 3, the ground electrode 4 is located on a main surface of the fourth insulating layer 14 on a side opposite to the first insulating layer 11. In the multilayer substrate 100B according to example embodiment 3, the ground electrode 4 overlaps a region of at least half of the first signal line 21 in the width direction in the thickness direction D1 of the laminate substrate 1. In the width direction of the first signal line 21, the amount of overlapping between the ground electrode 4 and the first signal line 21 is greater than or equal to half of the line width W21 of the first signal line 21 and less than the line width W21 of the first signal line 21. In plan view from the thickness direction D1 of the laminate substrate 1, the ground electrode 4 is disposed so as to overlap a first edge of the first signal line 21 among the first edge and a second edge thereof in the width direction, but may be disposed between the first edge and the second edge of the first signal line 21 in the width direction so as to overlap neither the first edge nor the second edge. In the present example embodiment, the width W4 of the ground electrode 4 is smaller than the line width W21 of the first signal line 21 in the width direction of the first signal line 21.

Further, in the multilayer substrate 100B, the alternating current signal line 2 further includes the signal line 24 (hereinafter, also referred to as the third signal line 24) adjacent to the ground electrode 4 in the width direction of the first signal line 21. In the thickness direction D1 of the laminate substrate 1, the third signal line 24 overlaps the first signal line 21 and is spaced apart from the first signal line 21. That is, in the present example embodiment, the alternating current signal line 2 has the signal lines 21 to 24 spaced apart from each other in the thickness direction of the laminate substrate 1. In example embodiment 3, a plurality of connection conductors that electrically connect the signal lines 21 to 24 in the alternating current signal line 2 include a plurality of first connection conductors 32 penetrating the second insulating layer 12, a plurality of third connection conductors 31 penetrating the first insulating layer 11, a plurality of fourth connection conductors 34 penetrating the fourth insulating layer 14, and a plurality of second connection conductors 33 penetrating the third insulating layer 13. In the present example embodiment, the second connection conductors 33 and the fourth connection conductors 34 correspond to each other on a one-to-one basis, and the second connection conductor 33 and the fourth connection conductor 34 corresponding to each other overlap in the thickness direction D1 of the laminate substrate 1. Further, in the present example embodiment, the first connection conductor 32, the third connection conductor 31, and the fourth connection conductor 34 overlap each other in the thickness direction D1 of the laminate substrate 1. However, the first connection conductor 32, the third connection conductor 31, and the fourth connection conductor 34 may be shifted from each other in a direction in which a signal is transmitted (the Y-axis direction, in the example of FIG. 5).

The third signal line 24 is located on the main surface of the fourth insulating layer 14 on the side opposite to the first insulating layer 11. Accordingly, in the present example embodiment, the third signal line 24 and the ground electrode 4 are formed on the main surface of the fourth insulating layer 14 on the side opposite to the first insulating layer 11. The thickness T24 of the third signal line 24 is the same as the thickness T4 of the ground electrode 4 in the thickness direction D1 of the laminate substrate 1. In example embodiment 3, each of the thickness T4 of the ground electrode 4 and the thickness T24 of the third signal line 24 is the same as the thickness T22 of the second signal line 22. In example embodiment 3, as an example, the thickness T21 of the first signal line 21, the thickness T22 of the second signal line 22, the thickness T23 of the signal line 23, the thickness T4 of the ground electrode 4, and the thickness T24 of the third signal line 24 are about 18 μm, about 12 μm, about 12 μm, 12 μm, and 12 μm, respectively.

The width W24 of the third signal line 24 adjacent to the ground electrode 4 in the width direction of the first signal line 21 is smaller than the width W4 of the ground electrode 4. It is preferable that the width W24 of the third signal line 24 be larger in terms of reducing the alternating current resistance of the alternating current signal line 2.

In the multilayer substrate 100B according to example embodiment 3, similarly to the multilayer substrate 100 according to example embodiment 1, the thickness T21 of the first signal line 21 overlapping the ground electrode 4 in the thickness direction D1 of the laminate substrate 1 is larger than the thickness T22 of the second signal line 22. Thus, it is possible to reduce the alternating current resistance of the alternating current signal line 2 while suppressing an increase in the overall thickness of the multilayer substrate 100B.

Further, in the multilayer substrate 100B according to example embodiment 3, the alternating current signal line 2 further includes the third signal line 24 adjacent to the ground electrode 4 in the width direction of the first signal line 21.

With the above configuration, the cross-sectional area of the alternating current signal line 2 can be further increased, and the alternating current resistance of the alternating current signal line 2 can be further reduced.

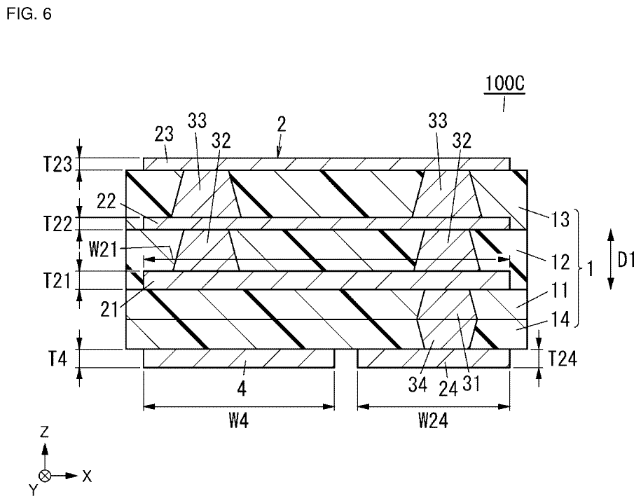

A multilayer substrate 100C according to example embodiment 4 is described with reference to FIG. 6. For the multilayer substrate 100C according to example embodiment 4, components similar to those of the multilayer substrate 100B according to example embodiment 3 (see FIG. 5) are given the same reference numerals, and description thereof is omitted. In FIG. 6, similarly to FIG. 5, a Cartesian coordinate system having three axes of an X-axis, a Y-axis, and a Z-axis orthogonal to each other is defined, and an axis along the thickness direction D1 of the laminate substrate 1 is indicated as the Z-axis.

The multilayer substrate 100C according to example embodiment 4 is different from the multilayer substrate 100B according to example embodiment 3 in that the thickness T4 of the ground electrode 4 and the thickness T24 of the third signal line 24 are larger than the thickness T22 of the second signal line 22. In example embodiment 4, as an example, the thickness T21 of the first signal line 21, the thickness T22 of the second signal line 22, the thickness T23 of the signal line 23, the thickness T4 of the ground electrode 4, and the thickness T24 of the third signal line 24 are about 18 μm, about 12 μm, about 12 μm, about 18 μm, and about 18 μm, respectively.

In example embodiment 4, each of the thickness T4 of the ground electrode 4 and the thickness T24 of the third signal line 24 is the same as the thickness T21 of the first signal line 21, but may be different from the thickness T21 of the first signal line 21.

In the multilayer substrate 100C according to example embodiment 4, the thickness T4 of the ground electrode 4 and the thickness T24 of the third signal line 24 are larger than the thickness T22 of the second signal line 22 in the thickness direction D1 of the laminate substrate 1.

With the above configuration, the thickness T21 of the first signal line 21 adjacent to the ground electrode 4 in the thickness direction D1 of the laminate substrate 1 and the thickness T24 of the third signal line 24 adjacent to the ground electrode 4 in a width direction of the ground electrode 4 are larger than the thickness T22 of the second signal line 22. This makes it possible to reduce the alternating current resistance of the alternating current signal line 2 while suppressing an increase in the overall thickness of the multilayer substrate 100C.

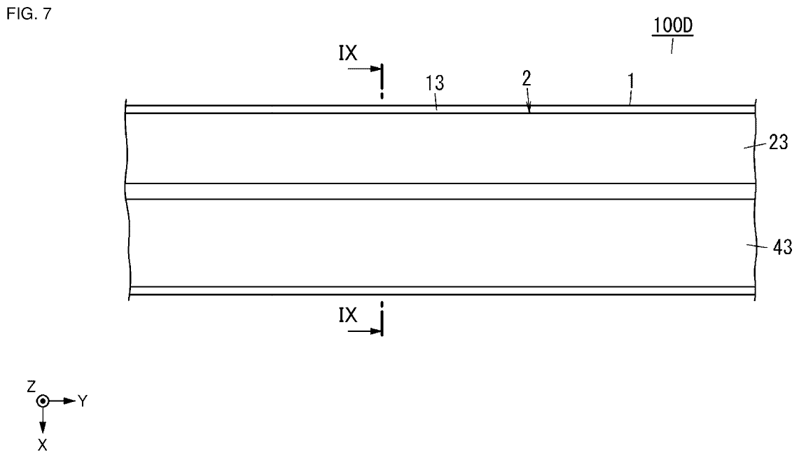

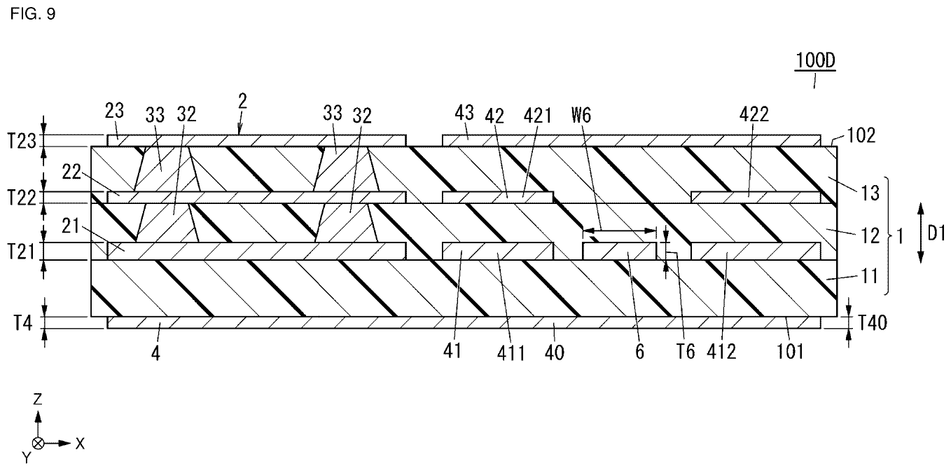

A multilayer substrate 100D according to example embodiment 5 is described with reference to FIGS. 7 to 9. For the multilayer substrate 100D according to example embodiment 5, components similar to those of the multilayer substrate 100 according to example embodiment 1 (see FIGS. 1 to 3) are given the same reference numerals, and description thereof is omitted. In each of FIGS. 7 to 9, similarly to FIGS. 1 to 3, a Cartesian coordinate system having three axes of an X-axis, a Y-axis, and a Z-axis orthogonal to each other is defined, and an axis along the thickness direction D1 (see FIG. 9) of the laminate substrate 1 is indicated as the Z-axis.

The multilayer substrate 100D according to example embodiment 5 is different from the multilayer substrate 100 according to example embodiment 1 in that, as depicted in FIG. 9, the multilayer substrate 100D further includes an RF signal line 6, a second ground electrode 40, and a third ground electrode 43. The width of the multilayer substrate 100D is larger than the width of the multilayer substrate 100 in the width direction of the first signal line 21.

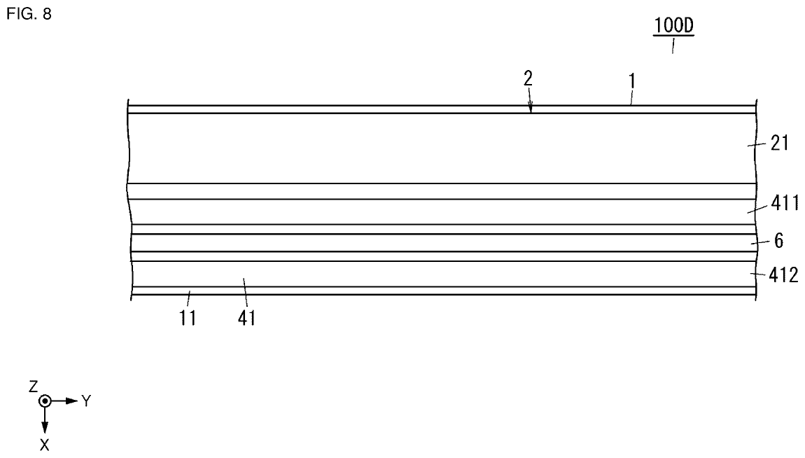

In the present example embodiment, as depicted in FIG. 8, the RF signal line 6 has a linear shape in plan view from the thickness direction D1 of the laminate substrate 1. The RF signal line 6 is located in the laminate substrate 1. As depicted in FIG. 9, the second ground electrode 40 is located on the laminate substrate 1. The second ground electrode 40 is opposed to the RF signal line 6 with one insulating layer 11 among the insulating layers 11 to 13 interposed therebetween in the thickness direction D1 of the laminate substrate 1, and is different from the first ground electrode 4, which is the ground electrode 4. The third ground electrode 43 is located on the laminate substrate 1. The third ground electrode 43 is opposed to the RF signal line 6 with the insulating layers 12 and 13 different from the insulating layer 11 among the insulating layers 11 to 13 interposed therebetween in the thickness direction D1 of the laminate substrate 1. In the present example embodiment, as depicted in FIG. 7, the third ground electrode 43 has a linear shape in plan view from the thickness direction D1 of the laminate substrate 1. Each of the RF signal line 6 and the third ground electrode 43 may have a shape different from the linear shape in plan view from the thickness direction D1 of the laminate substrate 1.

Further, as depicted in FIG. 9, the multilayer substrate 100D further includes a fourth ground electrode 41 and a fifth ground electrode 42. In the multilayer substrate 100D, in the thickness direction D1 of the laminate substrate 1, the second ground electrode 40, the fourth ground electrode 41, the fifth ground electrode 42, and the third ground electrode 43 are arranged in order of the second ground electrode 40, the fourth ground electrode 41, the fifth ground electrode 42, and the third ground electrode 43. The second ground electrode 40, the fourth ground electrode 41, the fifth ground electrode 42, and the third ground electrode 43 are spaced apart from each other in the thickness direction D1 of the laminate substrate 1. Further, in the multilayer substrate 100D, the fourth ground electrode 41 is divided into two split ground electrodes 411 and 412 in the width direction of the first signal line 21. Further, in the multilayer substrate 100D, the fifth ground electrode 42 is divided into two split ground electrodes 421 and 422 in the width direction of the second signal line 22.

In the present example embodiment, the first signal line 21 and the RF signal line 6 are arranged in the width direction of the first signal line 21. Specifically, in the present example embodiment, in the width direction of the first signal line 21, the first signal line 21, the split ground electrode 411, the RF signal line 6, and the split ground electrode 412 are arranged in order of the first signal line 21, the split ground electrode 411, the RF signal line 6, and the split ground electrode 412. The first signal line 21, the split ground electrode 411, the RF signal line 6, and the split ground electrode 412 are spaced apart from each other in the width direction of the first signal line 21. In the present example embodiment, the first signal line 21, the split ground electrode 411, the RF signal line 6, and the split ground electrode 412 are formed, for example, by patterning the first copper foil applied to the first insulating layer 11.

Further, in the present example embodiment, in the width direction of the second signal line 22, the second signal line 22, the split ground electrode 421, and the split ground electrode 422 are arranged in order of the second signal line 22, the split ground electrode 421, and the split ground electrode 422. The second signal line 22, the split ground electrode 421, and the split ground electrode 422 are spaced apart from each other in the width direction of the second signal line 22. A distance between the split ground electrode 421 and the split ground electrode 422 is longer than a width W6 of the RF signal line 6 in the width direction of the second signal line 22. The split ground electrode 421 and the split ground electrode 422 do not overlap the RF signal line 6 in the thickness direction D1 of the laminate substrate 1. In the present example embodiment, the second signal line 22, the split ground electrode 421, and the split ground electrode 422 are formed, for example, by patterning the second copper foil applied to the second insulating layer 12.

In the present example embodiment, the signal line 23 and the third ground electrode 43 are formed, for example, by patterning the third copper foil applied to the third insulating layer 13.

The first ground electrode 4 and the second ground electrode 40 are located on the main surface 101 of the laminate substrate 1. The second ground electrode 40 is connected to the first ground electrode 4. In the present example embodiment, the second ground electrode 40 and the first ground electrode 4 are integrated, and the second ground electrode 40 and the first ground electrode 4 are seamlessly connected. In the present example embodiment, the first ground electrode 4 and the second ground electrode 40 are formed, for example, by patterning the fourth copper foil applied to the second main surface on the side opposite to the first main surface that is the main surface of the first insulating layer 11 to which the first copper foil is applied.

The RF signal line 6 is designed, for example, such that the impedance of the RF signal line 6 is about 50 Ω. As depicted in FIG. 9, the RF signal line 6 is located between the second ground electrode 40 and the third ground electrode 43 in the thickness direction D1 of the laminate substrate 1. Accordingly, in the multilayer substrate 100D, a stripline is defined by the laminate substrate 1, the RF signal line 6, the second ground electrode 40, and the third ground electrode 43.

In the multilayer substrate 100D according to example embodiment 5, similarly to the multilayer substrate 100 according to example embodiment 1, the thickness T21 of the first signal line 21 overlapping the ground electrode 4 in the thickness direction D1 of the laminate substrate 1 is larger than the thickness T22 of the second signal line 22. Thus, it is possible to reduce the alternating current resistance of the alternating current signal line 2 while suppressing an increase in the overall thickness of the multilayer substrate 100D.

Further, because the multilayer substrate 100D according to example embodiment 5 includes the stripline including the laminate substrate 1, the RF signal line 6, the second ground electrode 40, and the third ground electrode 43, it is also possible to use the multilayer substrate 100D for transmission of a high frequency signal by the RF signal line 6 in addition to transmission of a signal by the alternating current signal line 2.

Further, in the multilayer substrate 100D according to example embodiment 5, the first signal line 21 and the RF signal line 6 are arranged in the width direction of the first signal line 21. A thickness T6 of the RF signal line 6 is the same as the thickness T21 of the first signal line 21 in the thickness direction D1 of the laminate substrate 1.

With the above configuration, the resistance value of the RF signal line 6 can be reduced, and transmission loss of a high frequency signal in the RF signal line 6 can be reduced.

Further, in the multilayer substrate 100D according to example embodiment 5, the first ground electrode 4 and the second ground electrode 40 are located on the main surface 101 of the laminate substrate 1. The second ground electrode 40 is connected to the first ground electrode 4.

With the above configuration, the noise resistance can be improved.

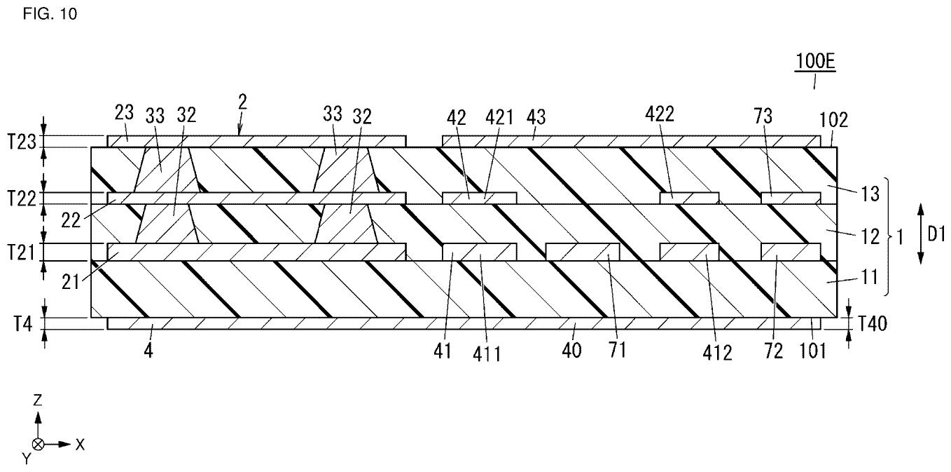

A multilayer substrate 100E according to example embodiment 6 is described with reference to FIG. 10. For the multilayer substrate 100E according to example embodiment 6, components similar to those of the multilayer substrate 100D according to example embodiment 5 (see FIGS. 7 to 9) are given the same reference numerals, and description thereof is omitted. In FIG. 10, similarly to FIGS. 7 to 9, a Cartesian coordinate system having three axes of an X-axis, a Y-axis, and a Z-axis orthogonal to each other is defined, and an axis along the thickness direction D1 (see FIG. 10) of the laminate substrate 1 is indicated as the Z-axis.

The multilayer substrate 100E according to example embodiment 6 is different from the multilayer substrate 100D according to example embodiment 5 in that the multilayer substrate 100E includes a plurality of (three, in FIG. 10) signal conductor lines 71 to 73.

The signal conductor lines 71 to 73 are located in the laminate substrate 1. In the present example embodiment, each of the signal conductor lines 71 to 73 has, for example, a linear shape in plan view from the thickness direction D1 of the laminate substrate 1. Each of the signal conductor lines 71 to 73 may have a shape different from the linear shape in plan view from the thickness direction D1 of the laminate substrate 1.

In the present example embodiment, the first signal line 21 and two signal conductor lines 71 and 72 are arranged in the width direction of the first signal line 21. Specifically, in the present example embodiment, in the width direction of the first signal line 21, the first signal line 21, the split ground electrode 411, the signal conductor line 71, the split ground electrode 412, and the signal conductor line 72 are arranged in order of the first signal line 21, the split ground electrode 411, the signal conductor line 71, the split ground electrode 412, and the signal conductor line 72. The first signal line 21, the split ground electrode 411, the signal conductor line 71, the split ground electrode 412, and the signal conductor line 72 are spaced apart from each other in the width direction of the first signal line 21. In the present example embodiment, the first signal line 21, the split ground electrode 411, the signal conductor line 71, the split ground electrode 412, and the signal conductor line 72 are formed, for example, by patterning the first copper foil applied to the first insulating layer 11.

Further, in the present example embodiment, the second signal line 22 and one signal conductor line 73 are arranged in the width direction of the second signal line 22. Specifically, in the present example embodiment, in the width direction of the second signal line 22, the second signal line 22, the split ground electrode 421, the split ground electrode 422, and the signal conductor line 73 are arranged in order of the second signal line 22, the split ground electrode 421, the split ground electrode 422, and the signal conductor line 73. The second signal line 22, the split ground electrode 421, the split ground electrode 422, and the signal conductor line 73 are spaced apart from each other in the width direction of the second signal line 22. The split ground electrode 421 and the split ground electrode 422 do not overlap the signal conductor line 71 in the thickness direction D1 of the laminate substrate 1. In the present example embodiment, the second signal line 22, the split ground electrode 421, the split ground electrode 422, and the signal conductor line 73 are formed, for example, by patterning the second copper foil applied to the second insulating layer 12.

In the present example embodiment, the signal line 23 and the third ground electrode 43 are formed, for example, by patterning the third copper foil applied to the third insulating layer 13.

In the present example embodiment, the first ground electrode 4 and the second ground electrode 40 are formed, for example, by patterning the fourth copper foil applied to the second main surface on the side opposite to the first main surface that is the main surface of the first insulating layer 11 to which the first copper foil is applied.

As is understood from the above description, the number of signal conductor lines arranged with the first signal line 21 in the width direction of the first signal line 21 is the largest among the signal conductor lines 71 to 73.

In the multilayer substrate 100E according to example embodiment 6, similarly to the multilayer substrate 100D according to example embodiment 5, the thickness T21 of the first signal line 21 overlapping the ground electrode 4 in the thickness direction D1 of the laminate substrate 1 is larger than the thickness T22 of the second signal line 22. Thus, it is possible to reduce the alternating current resistance of the alternating current signal line 2 while suppressing an increase in the overall thickness of the multilayer substrate 100E.

Further, because the multilayer substrate 100E according to example embodiment 6 further includes the signal conductor lines 71 to 73, it is also possible to use the multilayer substrate 100E for transmission of a plurality of other signals by each of the signal conductor lines 71 to 73 in addition to transmission of a signal by the alternating current signal line 2.

Further, in the multilayer substrate 100E according to example embodiment 6, the number of signal conductor lines arranged with the first signal line 21 in the width direction of the first signal line 21 is the largest among the signal conductor lines 71 to 73. Thus, it is possible to reduce the resistance value of a larger number of signal conductor lines among the signal conductor lines 71 to 73.

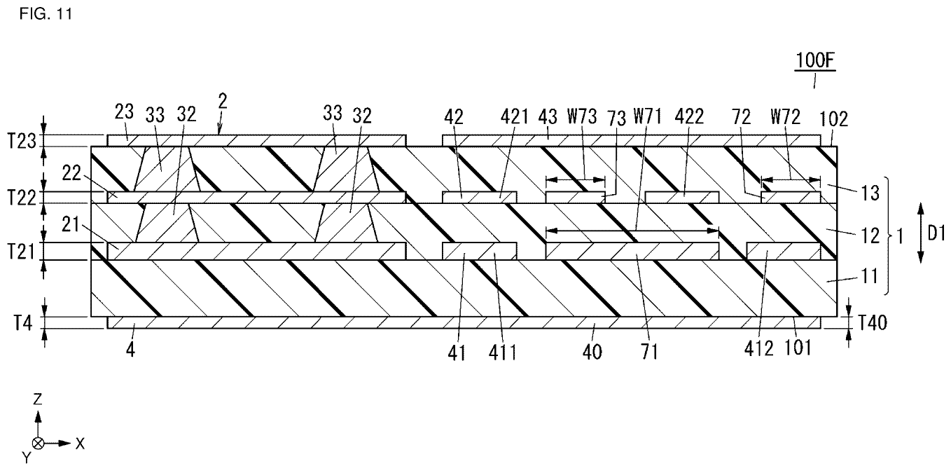

A multilayer substrate 100F according to example embodiment 7 is described with reference to FIG. 11. For the multilayer substrate 100F according to example embodiment 7, components similar to those of the multilayer substrate 100E according to example embodiment 6 (see FIG. 10) are given the same reference numerals, and description thereof is omitted. In FIG. 11, similarly to FIG. 10, a Cartesian coordinate system having three axes of an X-axis, a Y-axis, and a Z-axis orthogonal to each other is defined, and an axis along the thickness direction D1 (see FIG. 11) of the laminate substrate 1 is indicated as the Z-axis.

The multilayer substrate 100F according to example embodiment 7 is different from the multilayer substrate 100E according to example embodiment 6 in that the multilayer substrate 100F includes a plurality of (three, in FIG. 11) signal conductor lines 71 to 73 disposed as depicted in FIG. 11.

The signal conductor lines 71 to 73 are located in the laminate substrate 1. In the present example embodiment, each of the signal conductor lines 71 to 73 has, for example, a linear shape in plan view from the thickness direction D1 of the laminate substrate 1. The signal conductor lines 71 to 73 are signal conductor lines through which signals (for example, digital signals) different from each other are transmitted. Each of the signal conductor lines 71 to 73 may have a shape different from the linear shape in plan view from the thickness direction D1 of the laminate substrate 1.

In the present example embodiment, the first signal line 21 and one signal conductor line 71 are arranged in the width direction of the first signal line 21. Specifically, in the present example embodiment, in the width direction of the first signal line 21, the first signal line 21, the split ground electrode 411, the signal conductor line 71, and the split ground electrode 412 are arranged in order of the first signal line 21, the split ground electrode 411, the signal conductor line 71, and the split ground electrode 412. The first signal line 21, the split ground electrode 411, the signal conductor line 71, and the split ground electrode 412 are spaced apart from each other in the width direction of the first signal line 21. In the present example embodiment, the first signal line 21, the split ground electrode 411, the signal conductor line 71, and the split ground electrode 412 are formed, for example, by patterning the first copper foil applied to the first insulating layer 11.

Further, in the present example embodiment, the second signal line 22 and two signal conductor lines 73 and 72 are arranged in the width direction of the second signal line 22. Specifically, in the present example embodiment, in the width direction of the second signal line 22, the second signal line 22, the split ground electrode 421, the signal conductor line 73, the split ground electrode 422, and the signal conductor line 72 are arranged in order of the second signal line 22, the split ground electrode 421, the signal conductor line 73, the split ground electrode 422, and the signal conductor line 72. The second signal line 22, the split ground electrode 421, the signal conductor line 73, the split ground electrode 422, and the signal conductor line 72 are spaced apart from each other in the width direction of the second signal line 22. In the present example embodiment, the second signal line 22, the split ground electrode 421, the signal conductor line 73, the split ground electrode 422, and the signal conductor line 72 are formed, for example, by patterning the second copper foil applied to the second insulating layer 12.

In the present example embodiment, the signal line 23 and the third ground electrode 43 are formed, for example, by patterning the third copper foil applied to the third insulating layer 13.

In the present example embodiment, the first ground electrode 4 and the second ground electrode 40 are formed, for example, by patterning the fourth copper foil applied to the second main surface on the side opposite to the first main surface that is the main surface of the first insulating layer 11 to which the first copper foil is applied.

A width W71 of the signal conductor line 71 is larger than each of a width W72 of the signal conductor line 72 and a width W73 of the signal conductor line 73. Therefore, in the multilayer substrate 100F, the signal conductor line 71 having the largest width among the signal conductor lines 71 to 73 is arranged with the first signal line 21 in the width direction of the first signal line 21.

In the multilayer substrate 100F according to example embodiment 7, similarly to the multilayer substrate 100E according to example embodiment 6, the thickness T21 of the first signal line 21 overlapping the ground electrode 4 in the thickness direction D1 of the laminate substrate 1 is larger than the thickness T22 of the second signal line 22. Thus, it is possible to reduce the alternating current resistance of the alternating current signal line 2 while suppressing an increase in the overall thickness of the multilayer substrate 100F.

Further, because the multilayer substrate 100F according to example embodiment 7 further includes the signal conductor lines 71 to 73, it is also possible to use the multilayer substrate 100F for transmission of a plurality of other signals by each of the signal conductor lines 71 to 73 in addition to transmission of a signal by the alternating current signal line 2.

Further, in the multilayer substrate 100F according to example embodiment 7, the signal conductor line 71 having the largest width among the signal conductor lines 71 to 73 is arranged with the first signal line 21 in the width direction of the first signal line 21.

With the above configuration, it is possible to reduce the resistance value of the signal conductor line 71 having the largest width among the signal conductor lines 71 to 73.

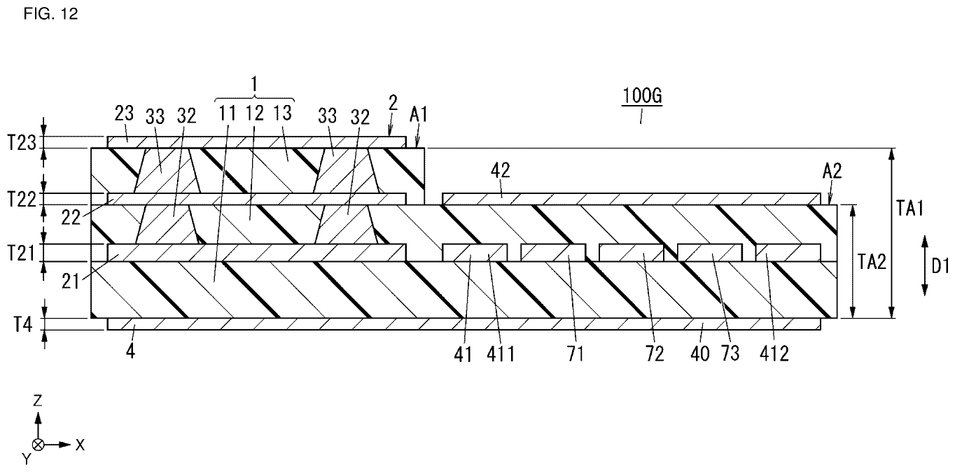

A multilayer substrate 100G according to example embodiment 8 is described with reference to FIG. 12. For the multilayer substrate 100G according to example embodiment 8, components similar to those of the multilayer substrate 100E according to example embodiment 6 (see FIG. 10) are given the same reference numerals, and description thereof is omitted. In FIG. 12, similarly to FIG. 10, a Cartesian coordinate system having three axes of an X-axis, a Y-axis, and a Z-axis orthogonal to each other is defined, and an axis along the thickness direction D1 (see FIG. 12) of the laminate substrate 1 is indicated as the Z-axis.

The multilayer substrate 100G according to example embodiment 8 is different from the multilayer substrate 100E according to example embodiment 6 in that a thickness TA2 of a second region A2 in which a plurality of (three, in FIG. 12) signal conductor lines 71 to 73 are located in the laminate substrate 1 is smaller than a thickness TA1 of a first region A1 in which the signal lines 21 to 23 and the ground electrode 4 are located in the laminate substrate 1.

In the present example embodiment, the first signal line 21 and the three signal conductor lines 71 to 73 are arranged in the width direction of the first signal line 21. Specifically, in the present example embodiment, in the width direction of the first signal line 21, the first signal line 21, the split ground electrode 411, the signal conductor line 71, the signal conductor line 72, the signal conductor line 73, and the split ground electrode 412 are arranged in order of the first signal line 21, the split ground electrode 411, the signal conductor line 71, the signal conductor line 72, the signal conductor line 73, and the split ground electrode 412. In the present example embodiment, the first signal line 21, the split ground electrode 411, the signal conductor line 71, the signal conductor line 72, the signal conductor line 73, and the split ground electrode 412 are formed, for example, by patterning the first copper foil applied to the first insulating layer 11.

Further, in the present example embodiment, in the width direction of the second signal line 22, the second signal line 22 and the fifth ground electrode 42 are arranged in order of the second signal line 22 and the fifth ground electrode 42. The second signal line 22 and the fifth ground electrode 42 are spaced apart from each other in the width direction of the second signal line 22. In the present example embodiment, the second signal line 22 and the fifth ground electrode 42 are formed, for example, by patterning the second copper foil applied to the second insulating layer 12.

Further, in the present example embodiment, the signal line 23 is formed, for example, by patterning the third copper foil applied to the third insulating layer 13.

In the present example embodiment, the first ground electrode 4 and the second ground electrode 40 are formed, for example, by patterning the fourth copper foil applied to the second main surface on the side opposite to the first main surface that is the main surface of the first insulating layer 11 to which the first copper foil is applied.

In the multilayer substrate 100G according to example embodiment 8, similarly to the multilayer substrate 100E according to example embodiment 6, the thickness T21 of the first signal line 21 overlapping the ground electrode 4 in the thickness direction D1 of the laminate substrate 1 is larger than the thickness T22 of the second signal line 22. Thus, it is possible to reduce the alternating current resistance of the alternating current signal line 2 while suppressing an increase in the overall thickness of the multilayer substrate 100G.

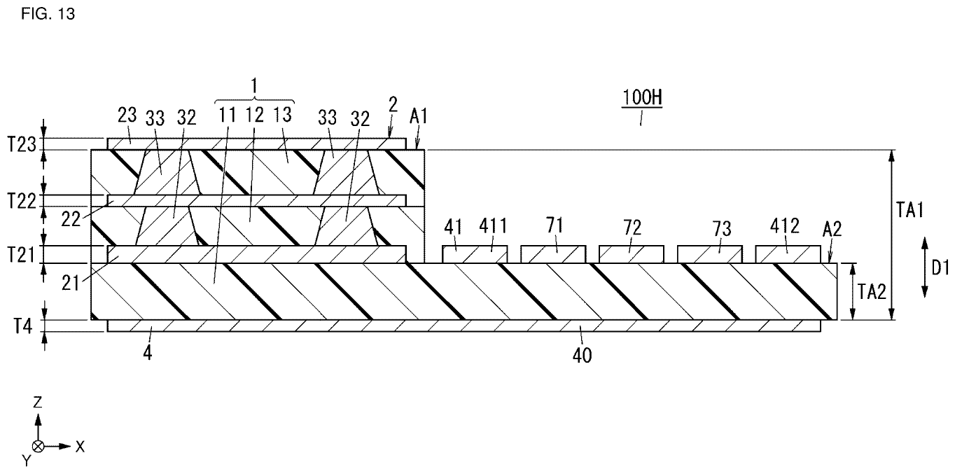

A multilayer substrate 100H according to example embodiment 9 is described with reference to FIG. 13. For the multilayer substrate 100H according to example embodiment 9, components similar to those of the multilayer substrate 100G according to example embodiment 8 (see FIG. 12) are given the same reference numerals, and description thereof is omitted. In FIG. 13, similarly to FIG. 12, a Cartesian coordinate system having three axes of an X-axis, a Y-axis, and a Z-axis orthogonal to each other is defined, and an axis along the thickness direction D1 (see FIG. 13) of the laminate substrate 1 is indicated as the Z-axis.

The multilayer substrate 100H according to example embodiment 9 is different from the multilayer substrate 100G according to example embodiment 8 in that the thickness TA2 of the second region A2 on which the plurality of (three, in FIG. 13) signal conductor lines 71 to 73 are located in the laminate substrate 1 is the same as the thickness of the insulating layer 11.

In the multilayer substrate 100H according to example embodiment 9, similarly to the multilayer substrate 100G according to example embodiment 8, the thickness T21 of the first signal line 21 overlapping the ground electrode 4 in the thickness direction D1 of the laminate substrate 1 is larger than the thickness T22 of the second signal line 22. Thus, it is possible to reduce the alternating current resistance of the alternating current signal line 2 while suppressing an increase in the overall thickness of the multilayer substrate 100H.

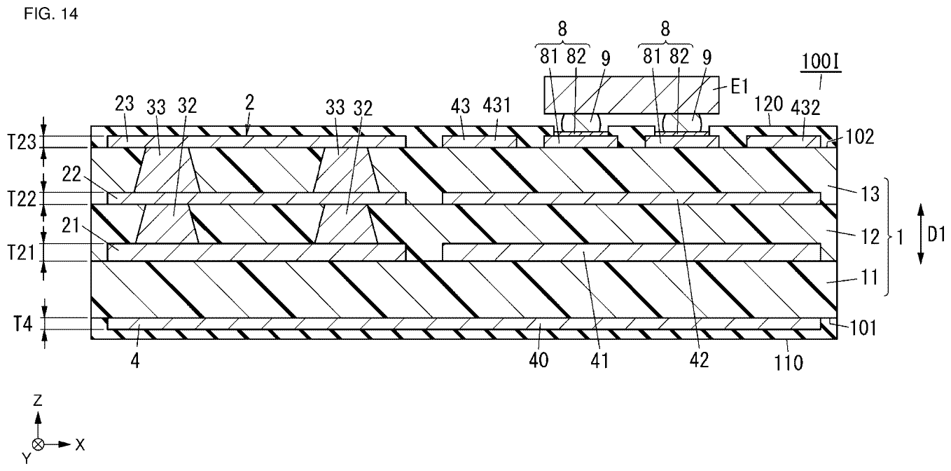

A multilayer substrate 100I according to example embodiment 10 is described with reference to FIG. 14. For the multilayer substrate 100I according to example embodiment 10, components similar to those of the multilayer substrate 100G according to example embodiment 8 (see FIG. 12) are given the same reference numerals, and description thereof is omitted. In FIG. 14, similarly to FIG. 12, a Cartesian coordinate system having three axes of an X-axis, a Y-axis, and a Z-axis orthogonal to each other is defined, and an axis along the thickness direction D1 (see FIG. 14) of the laminate substrate 1 is indicated as the Z-axis.

The multilayer substrate 100I according to example embodiment 10 is different from the multilayer substrate 100G according to example embodiment 8 in that the multilayer substrate 100I includes a plurality of land electrodes 8. The plurality of land electrodes 8 are located on the laminate substrate 1.

In the present example embodiment, the third ground electrode 43 is divided into two split ground electrodes 431 and 432. The land electrodes 8 are arranged with the signal line 23 in the width direction of the signal line 23. Specifically, in the present example embodiment, the signal line 23, the split ground electrode 431, the land electrode 8, the land electrode 8, and the split ground electrode 432 are arranged in order of the signal line 23, the split ground electrode 431, the land electrode 8, the land electrode 8, and the split ground electrode 432.

In the present example embodiment, a thickness of the land electrodes 8 is smaller than the thickness T21 of the first signal line 21. Each of the land electrodes 8 includes a conductor portion 81 having the same thickness as the thickness T23 of the signal line 23 and a plating portion 82 laminated on the conductor portion 81. The multilayer substrate 100I further includes a first protective film 110 disposed on the first main surface 101 of the laminate substrate 1 and a second protective film 120 disposed on the second main surface 102 of the laminate substrate 1. Each of the first protective film 110 and the second protective film 120 includes, for example, a polyimide film and an adhesive layer. A material of the adhesive layer includes, for example, an acrylic resin, a silicone resin, an epoxy resin, or a urethane resin. If the multilayer substrate 100I has no bent portion, each of the first protective film 110 and the second protective film 120 is not limited to the configuration including the polyimide film and the adhesive layer, and may be, for example, a protective film formed using a spin coating technique and a photolithography technique.

The signal line 23, the split ground electrode 431, the conductor portion 81 of the land electrode 8, the conductor portion 81 of the land electrode 8, and the split ground electrode 432 are formed, for example, by patterning the third copper foil applied to the third insulating layer 13.

Further, the multilayer substrate 100I according to example embodiment 10 further includes a plurality of solder portions 9 joined to the plurality of land electrodes 8 on a one-to-one basis and an electronic component E1 joined to the plurality of solder portions 9.

The electronic component E1 is, for example, a connector. The electronic component E1 is not limited to a connector and may be another electronic component such as, for example, an IC chip or a surface-mount electronic component (for example, a chip inductor, a chip capacitor, or the like).

Although the multilayer substrate 100I includes the solder portions 9 and the electronic component E1, the multilayer substrate 100I may have a configuration that does not include the solder portions 9 and the electronic component E1.

In the multilayer substrate 100I according to example embodiment 10, similarly to the multilayer substrate 100G according to example embodiment 8, the thickness T21 of the first signal line 21 overlapping the ground electrode 4 in the thickness direction D1 of the laminate substrate 1 is larger than the thickness T22 of the second signal line 22. Thus, it is possible to reduce the alternating current resistance of the alternating current signal line 2 while suppressing an increase in the overall thickness of the multilayer substrate 100I.

Further, the multilayer substrate 100I according to example embodiment 10 further includes the land electrodes 8 located on the laminate substrate 1. The thickness of the land electrodes 8 may be the same as the thickness T23 of one signal line 23 different from the first signal line 21 among the signal lines 21 to 23. The thickness T23 of the signal line 23 is the same as the thickness T22 of the second signal line 22, but may be different from the thickness T22 of the second signal line 22.

With the above configuration, the thickness of the land electrodes 8 can be made smaller than the thickness T21 of the first signal line 21. Thus, the heat capacity of each of the land electrodes 8 can be reduced, and the mounting efficiency of the electronic component E1 mounted on the land electrodes 8 can be improved.

Further, the multilayer substrate 100I according to example embodiment 10 further includes the solder portions 9 joined to the land electrodes 8 on a one-to-one basis and the electronic component E1 joined to the solder portions 9.

With the above configuration, the multilayer substrate 100I including the electronic component E1 can be provided.

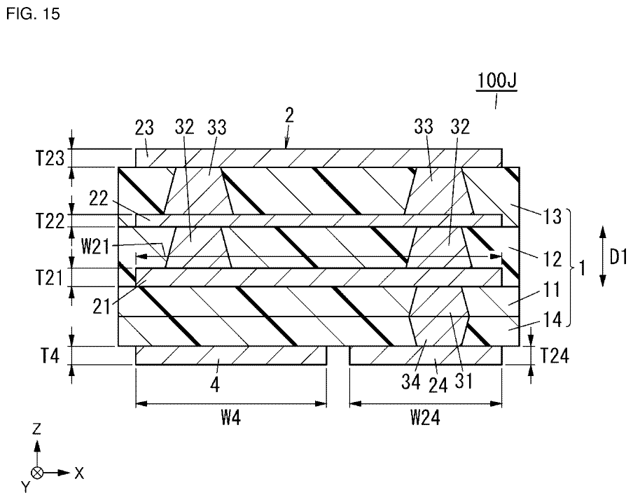

A multilayer substrate 100J according to example embodiment 11 is described with reference to FIG. 15. For the multilayer substrate 100J according to example embodiment 11, components similar to those of the multilayer substrate 100B according to example embodiment 3 (see FIG. 5) are given the same reference numerals, and description thereof is omitted. In FIG. 15, similarly to FIG. 5, a Cartesian coordinate system having three axes of an X-axis, a Y-axis, and a Z-axis orthogonal to each other is defined, and an axis along the thickness direction D1 (see FIG. 15) of the laminate substrate 1 is indicated as the Z-axis.

The multilayer substrate 100J according to example embodiment 11 is different from the multilayer substrate 100B according to example embodiment 3 in that the thickness T23 of the signal line 23 is larger than the thickness T22 of the second signal line 22. In example embodiment 11, the thickness T23 of the signal line 23 is the same as the thickness T21 of the first signal line 21, but may be different from the thickness T21 of the first signal line 21. In the multilayer substrate 100J according to example embodiment 11, similarly to the multilayer substrate 100B according to example embodiment 3, the thickness T21 of the first signal line 21 overlapping the ground electrode 4 in the thickness direction D1 of the laminate substrate 1 is larger than the thickness T22 of the second signal line 22. Thus, it is possible to reduce the alternating current resistance of the alternating current signal line 2 while suppressing an increase in the overall thickness of the multilayer substrate 100J.

Further, in the multilayer substrate 100J according to example embodiment 11, the thickness T23 of the signal line 23 is larger than the thickness T22 of the second signal line 22.

With the above configuration, the alternating current resistance of the alternating current signal line 2 can be further reduced.

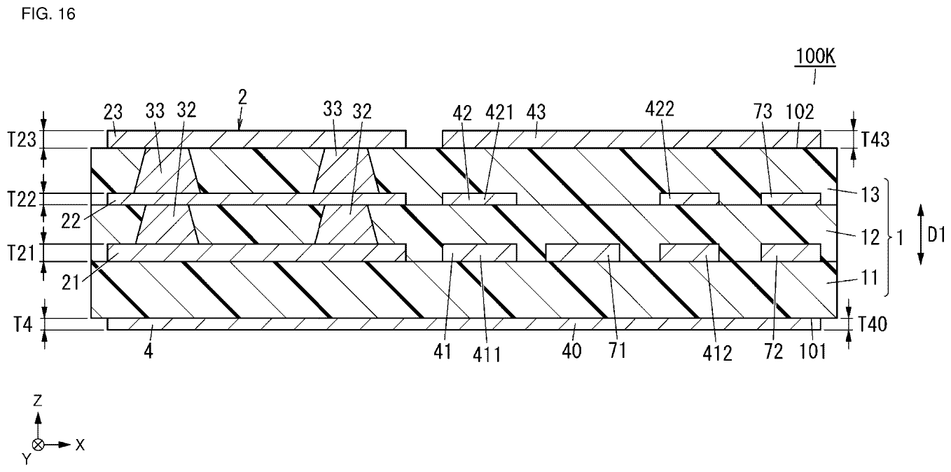

A multilayer substrate 100K according to example embodiment 12 is described with reference to FIG. 16. For the multilayer substrate 100K according to example embodiment 12, components similar to those of the multilayer substrate 100E according to example embodiment 6 (see FIG. 10) are given the same reference numerals, and description thereof is omitted. In FIG. 16, similarly to FIG. 10, a Cartesian coordinate system having three axes of an X-axis, a Y-axis, and a Z-axis orthogonal to each other is defined, and an axis along the thickness direction D1 (see FIG. 16) of the laminate substrate 1 is indicated as the Z-axis.

The multilayer substrate 100K according to example embodiment 12 is different from the multilayer substrate 100E according to example embodiment 6 in that the thickness T23 of the signal line 23 and a thickness T43 of the third ground electrode 43 are larger than the thickness T22 of the second signal line 22. In example embodiment 12, the thickness T23 of the signal line 23 and the thickness T43 of the third ground electrode 43 are the same as the thickness T21 of the first signal line 21, but may be different from the thickness T21 of the first signal line 21.

In the multilayer substrate 100K according to example embodiment 12, similarly to the multilayer substrate 100E according to example embodiment 6, the thickness T21 of the first signal line 21 overlapping the ground electrode 4 in the thickness direction D1 of the laminate substrate 1 is larger than the thickness T22 of the second signal line 22. Thus, it is possible to reduce the alternating current resistance of the alternating current signal line 2 while suppressing an increase in the overall thickness of the multilayer substrate 100K.

Further, in the multilayer substrate 100K according to example embodiment 12, the thickness T23 of the signal line 23 is larger than the thickness T22 of the second signal line 22.

With the above configuration, the alternating current resistance of the alternating current signal line 2 can be further reduced.

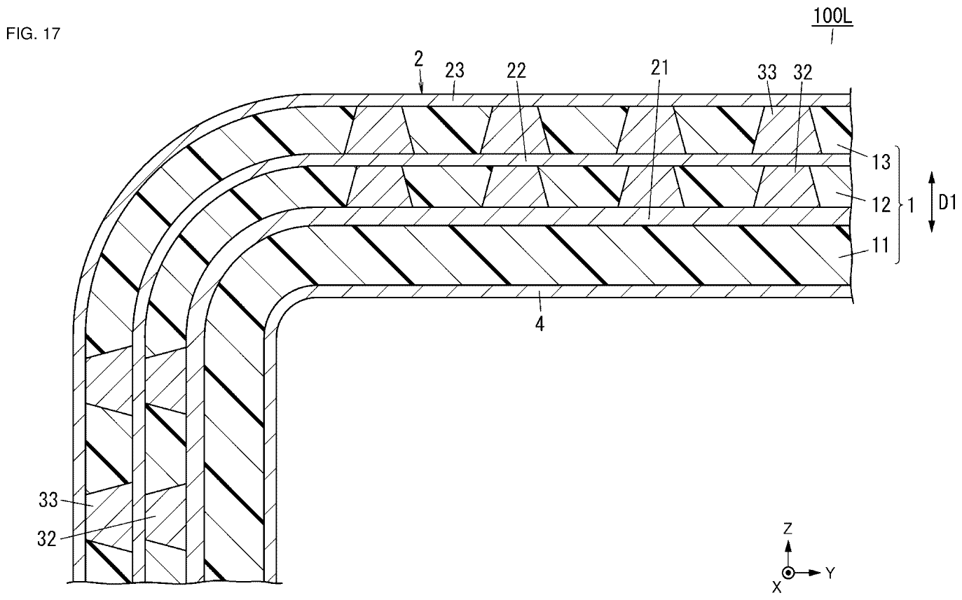

A multilayer substrate 100L according to example embodiment 13 is described with reference to FIG. 17. For the multilayer substrate 100L according to example embodiment 13, components similar to those of the multilayer substrate 100 according to example embodiment 1 (see FIGS. 1 to 3) are given the same reference numerals, and description thereof is omitted. In FIG. 17, similarly to FIGS. 1 to 3, a Cartesian coordinate system having three axes of an X-axis, a Y-axis, and a Z-axis orthogonal to each other is defined and indicated.

The multilayer substrate 100L according to example embodiment 13 is different from the multilayer substrate 100 according to example embodiment 1 in that the multilayer substrate 100L is bent as depicted in FIG. 17.

Bending processing for the multilayer substrate 100L is performed by plastically deforming a thermoplastic resin of the laminate substrate 1, and the multilayer substrate 100L maintains its shape by itself.

The multilayer substrate 100L according to example embodiment 13 can reduce the alternating current resistance similarly to the multilayer substrate 100 according to example embodiment 1.

Further, for example, disposition of the multilayer substrate 100L according to example embodiment 13 in a housing of electronic equipment is facilitated when a storage space for the multilayer substrate 100L is a curved space in the housing of the electronic equipment.

The above example embodiments 1 to 13 and the like are merely some of various example embodiments of the present invention. The above example embodiments 1 to 13 and the like can be variously modified depending on design and the like and may be combined as appropriate as long as the object of the present invention can be achieved.

For example, a material of each of the insulating layers 11 to 13 may be, for example, polyimide (PI) or modified polyimide (Modified-PI). In this case, each of the first connection conductors 32 and the second connection conductors 33 may be formed of a through-hole plating layer. Further, the first connection conductor 32 and the third connection conductor 31 connected to each other may be formed of one through-hole plating layer. A material of the through-hole plating layer is, for example, copper. Further, the laminate substrate 1 may include an adhesive layer interposed between two insulating layers adjacent to each other in the thickness direction D1 of the laminate substrate 1 among the insulating layers 11 to 13.

Further, the multilayer substrates 100A to 100K of example embodiments 2 to 12 may be bent similarly to the multilayer substrate 100L according to example embodiment 13.

Further, the multilayer substrates 100, 100A to 100H, and 100J to 100L may further include at least one of a first protective film disposed on the first main surface 101 of the laminate substrate 1 or a second protective film disposed on the second main surface 102 of the laminate substrate 1. Each of the first protective film and the second protective film includes, for example, a polyimide film and an adhesive layer. A material of the adhesive layer includes, for example, an acrylic resin, a silicone resin, an epoxy resin, or a urethane resin. If the multilayer substrates 100, 100A to 100H, and 100J to 100K have no bent portion, each of the first protective film and the second protective film is not limited to the configuration including the polyimide film and the adhesive layer, and may be, for example, a protective film formed using a spin coating technique and a photolithography technique.

The following example embodiments are disclosed in the present specification.

A multilayer substrate (100; 100A; 100B; 100C; 100D; 100E; 100F; 100G; 100H; 100I; 100J; 100K; 100L) according to a first example embodiment includes a laminate substrate (1), an alternating current signal line (2), and a ground electrode (4). A plurality of insulating layers (11 to 13; 11 to 14) are laminated in the laminate substrate (1). The alternating current signal line (2) is located in the laminate substrate (1). The ground electrode (4) is located on or in the laminate substrate (1). The ground electrode (4) overlaps the alternating current signal line (2) in a thickness direction (D1) of the laminate substrate (1). The alternating current signal line (2) includes a plurality of signal lines (21 to 23; 21 to 24) spaced apart from each other in the thickness direction (D1) of the laminate substrate (1). In the alternating current signal line (2), the plurality of signal lines (21 to 23; 21 to 24) are electrically connected by a plurality of connection conductors penetrating one of the plurality of insulating layers (11 to 13; 11 to 14) in the thickness direction (D1) of the laminate substrate (1). The plurality of signal lines (21 to 23; 21 to 24) include a first signal line (21) adjacent to the ground electrode (4) in the thickness direction (D1) of the laminate substrate (1) and a second signal line (22) adjacent to the first signal line (21) in the thickness direction (D1) of the laminate substrate (1). A thickness (T21) of the first signal line (21) is larger than a thickness (T22) of the second signal line (22) in the thickness direction (D1) of the laminate substrate (1).

According to this example embodiment, alternating current resistance can be reduced.

In a multilayer substrate (100; 100A; 100B; 100C; 100D; 100E; 100F; 100G; 100H; 100I; 100J; 100K; 100L) according to a second example embodiment, in the first example embodiment, the ground electrode (4) overlaps a region of at least half of the first signal line (21) in a width direction of the first signal line (21) in the thickness direction (D1) of the laminate substrate (1).

According to this example embodiment, compared with a case where a region that is less than half of the first signal line (21) in the width direction overlaps the ground electrode (4) in the thickness direction (D1) of the laminate substrate (1), unevenness of current density of the first signal line (21) in the width direction can be further reduced, and the alternating current resistance can be further reduced.

A multilayer substrate (100B; 100C; 100J) according to a third example embodiment is based on the second example embodiment. The plurality of signal lines (21 to 24) further include a third signal line (24) adjacent to the ground electrode (4) in the width direction of the first signal line (21).

According to this example embodiment, the alternating current resistance can be further reduced.

A multilayer substrate (100C; 100J) according to a fourth example embodiment is based on the third example embodiment. A thickness (T4) of the ground electrode (4) and a thickness (T24) of the third signal line (24) are larger than the thickness (T22) of the second signal line (22) in the thickness direction (D1) of the laminate substrate (1).

According to this example embodiment, because the thickness (T4) of the ground electrode (4) is larger than the thickness (T22) of the second signal line (22), the potential of the ground electrode (4) can be made more stable. Further, because the thickness (T24) of the third signal line (24) is larger than the thickness (T22) of the second signal line (22), the alternating current resistance can be further reduced.

A multilayer substrate (100D) according to a fifth example embodiment further includes an RF signal line (6), a second ground electrode (40), and a third ground electrode (43) in the first or second example embodiment. The RF signal line (6) is located in the laminate substrate (1). The second ground electrode (40) is located on the laminate substrate (1). The second ground electrode (40) is opposed to the RF signal line (6) with at least one insulating layer (11) among the plurality of insulating layers (11 to 13) interposed between the second ground electrode (40) and the RF signal line (6) in the thickness direction (D1) of the laminate substrate (1), and is different from a first ground electrode (4) that is the ground electrode (4). The third ground electrode (43) is located on the laminate substrate (1). The third ground electrode (43) is opposed to the RF signal line (6) with insulating layers (12 and 13) different from the above one insulating layer among the plurality of insulating layers (11 to 13) interposed between the third ground electrode (43) and the RF signal line (6) in the thickness direction (D1) of the laminate substrate (1).

According to this example embodiment, the multilayer substrate (100D) includes a stripline including the laminate substrate (1), the RF signal line (6), the second ground electrode (40), and the third ground electrode (43). Thus, it is also possible to use the multilayer substrate (100D) for transmission of a high frequency signal by the RF signal line (6) in addition to transmission of a signal by the alternating current signal line (2).

A multilayer substrate (100D) according to a sixth example embodiment is based on the fifth example embodiment. The first signal line (21) and the RF signal line (6) are arranged in a width direction of the first signal line (21). A thickness (T6) of the RF signal line (6) is the same as the thickness (T21) of the first signal line (21) in the thickness direction (D1) of the laminate substrate (1).

According to this example embodiment, the resistance value of the RF signal line (6) can be reduced, and transmission loss of a high frequency signal in the RF signal line (6) can be reduced.

A multilayer substrate (100D) according to a seventh example embodiment further includes the RF signal line (6), the second ground electrode (40), and the third ground electrode (43) in the fifth or sixth example embodiment. The RF signal line (6) is located in the laminate substrate (1). The second ground electrode (40) is located on the laminate substrate (1). The second ground electrode (40) is opposed to the RF signal line (6) with at least one insulating layer (11) among the plurality of insulating layers (11 to 13) interposed between the second ground electrode (40) and the RF signal line (6) in the thickness direction (D1) of the laminate substrate (1), and is different from the first ground electrode (4) that is the ground electrode (4). The third ground electrode (43) is located on the laminate substrate (1). The third ground electrode (43) is opposed to the RF signal line (6) with insulating layers (12 and 13) different from the above one insulating layer among the plurality of insulating layers (11 to 13) interposed between the third ground electrode (43) and the RF signal line (6) in the thickness direction (D1) of the laminate substrate (1). The first ground electrode (4) and the second ground electrode (40) are located on a main surface (101) of the laminate substrate (1). The second ground electrode (40) is connected to the first ground electrode (4).

According to this example embodiment, the multilayer substrate (100D) includes the stripline including the laminate substrate (1), the RF signal line (6), the second ground electrode (40), and the third ground electrode (43). Thus, it is also possible to use the multilayer substrate (100D) for transmission of a high frequency signal by the RF signal line (6) in addition to transmission of a signal by the alternating current signal line (2). Further, according to this example embodiment, noise resistance can be improved because the first ground electrode (4) and the second ground electrode (40) are located on the main surface (101) of the laminate substrate (1) and the second ground electrode (40) is connected to the first ground electrode (4).

A multilayer substrate (100E; 100G; 100H; 100K) according to an eighth example embodiment further includes a plurality of signal conductor lines (71 to 73) in the laminate substrate (1) in any one of the first to fourth example embodiments. The number of signal conductor lines arranged with the first signal line (21) in a width direction of the first signal line (21) is the largest among the plurality of signal conductor lines (71 to 73).

According to this example embodiment, because the multilayer substrate (100E; 100G; 100H; 100K) further includes the signal conductor lines (71 to 73), it is also possible to use the multilayer substrate (100E; 100G; 100H; 100K) for transmission of a plurality of other signals by each of the signal conductor lines (71 to 73) in addition to transmission of a signal by the alternating current signal line (2). Further, according to this example embodiment, because the number of signal conductor lines arranged with the first signal line (21) in the width direction of the first signal line (21) is the largest among the signal conductor lines (71 to 73), it is possible to reduce the resistance value of a larger number of signal conductor lines among the signal conductor lines (71 to 73).

A multilayer substrate (100F) according to a ninth example embodiment further includes a plurality of signal conductor lines (71 to 73) in the laminate substrate (1) in any one of the first to fourth example embodiments. In the multilayer substrate (100F), a signal conductor line (71) having the largest width among the plurality of signal conductor lines (71 to 73) is arranged with the first signal line (21) in a width direction of the first signal line (21).

According to this example embodiment, because the multilayer substrate (100F) further includes the signal conductor lines (71 to 73), it is also possible to use the multilayer substrate (100F) for transmission of a plurality of other signals by each of the signal conductor lines (71 to 73) in addition to transmission of a signal by the alternating current signal line (2). Further, according to this example embodiment, because the signal conductor line (71) having the largest width among the signal conductor lines (71 to 73) is arranged with the first signal line (21) in the width direction of the first signal line (21), it is possible to reduce the resistance value of the signal conductor line (71) having the largest width among the signal conductor lines (71 to 73).

A multilayer substrate (100I) according to a tenth example embodiment further includes a plurality of land electrodes (8) on the laminate substrate (1) in any one of the first to ninth example embodiments. A thickness of the plurality of land electrodes (8) is smaller than the thickness (T21) of the first signal line (21).

According to this example embodiment, the thickness of the land electrodes (8) can be made smaller than the thickness (T21) of the first signal line (21). Thus, the heat capacity of each of the land electrodes (8) can be reduced, and the mounting efficiency of an electronic component (E1) mounted on the land electrodes (8) can be improved.

A multilayer substrate (100I) according to an eleventh example embodiment further includes a plurality of solder portions (9) joined to the plurality of land electrodes (8) on a one-to-one basis and an electronic component (E1) joined to the plurality of solder portions (9) in the tenth example embodiment.

According to this example embodiment, the multilayer substrate (100I) including the electronic component (E1) can be provided.

In a multilayer substrate (100J; 100K) according to a twelfth example embodiment, in any one of the first to fourth example embodiments, a thickness (T23) of a signal line (23) farthest from the ground electrode (4) in the thickness direction (D1) of the laminate substrate (1) among the plurality of signal lines (21 to 23; 21 to 24) is larger than the thickness (T22) of the second signal line (22).

According to this example embodiment, the alternating current resistance of the alternating current signal line (2) can be further reduced.

In a multilayer substrate (100; 100A; 100B; 100C; 100D; 100E; 100F; 100G; 100H; 100I; 100J; 100K; 100L) according to a thirteenth example embodiment, in any one of the first to twelfth example embodiments, a material of each of the plurality of insulating layers (11 to 14) includes a thermoplastic resin.

According to this example embodiment, bendability of the multilayer substrate (100; 100A; 100B; 100C; 100D; 100E; 100F; 100G; 100H; 100I; 100J; 100K; 100L) is improved.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A multilayer substrate comprising:
a laminate substrate in which a plurality of insulating layers are laminated;
an alternating current signal line in the laminate substrate; and
a ground electrode on or in the laminate substrate and overlapping the alternating current signal line in a thickness direction of the laminate substrate; wherein
the alternating current signal line includes a plurality of signal lines spaced apart from each other in the thickness direction of the laminate substrate, and the plurality of signal lines are electrically connected by a plurality of connection conductors penetrating one of the plurality of insulating layers in the thickness direction of the laminate substrate;
the plurality of signal lines include:
a first signal line adjacent to the ground electrode in the thickness direction of the laminate substrate; and
a second signal line adjacent to the first signal line in the thickness direction of the laminate substrate; wherein
a thickness of the first signal line is larger than a thickness of the second signal line in the thickness direction of the laminate substrate.

2. The multilayer substrate according to claim 1, wherein the ground electrode overlaps a region of at least half of the first signal line in a width direction of the first signal line in the thickness direction of the laminate substrate.

3. The multilayer substrate according to claim 2, wherein the plurality of signal lines further include a third signal line adjacent to the ground electrode in the width direction of the first signal line.

4. The multilayer substrate according to claim 3, wherein a thickness of the ground electrode and a thickness of the third signal line are larger than the thickness of the second signal line in the thickness direction of the laminate substrate.

5. The multilayer substrate according to claim 1, further comprising:
an RF signal line in the laminate substrate;
a second ground electrode on the laminate substrate and opposed to the RF signal line with at least one insulating layer among the plurality of insulating layers interposed between the second ground electrode and the RF signal line in the thickness direction of the laminate substrate, the second ground electrode being different from a first ground electrode that is the ground electrode; and
a third ground electrode on the laminate substrate and opposed to the RF signal line with an insulating layer different from at least one insulating layer among the plurality of insulating layers interposed between the third ground electrode and the RF signal line in the thickness direction of the laminate substrate.

6. The multilayer substrate according to claim 5, wherein
the first signal line and the RF signal line are arranged in a width direction of the first signal line; and
a thickness of the RF signal line is equal or substantially equal to the thickness of the first signal line in the thickness direction of the laminate substrate.

7. The multilayer substrate according to claim 5, wherein
the first ground electrode and the second ground electrode are located on a main surface of the laminate substrate; and
the second ground electrode is connected to the first ground electrode.

8. The multilayer substrate according to claim 1, further comprising:
a plurality of signal conductor lines in the laminate substrate; wherein
a number of the plurality of signal conductor lines arranged with the first signal line in a width direction of the first signal line is largest among the plurality of signal conductor lines.

9. The multilayer substrate according to claim 1, further comprising:
a plurality of signal conductor lines in the laminate substrate; wherein
a signal conductor line having a largest width among the plurality of signal conductor lines is arranged with the first signal line in a width direction of the first signal line.

10. The multilayer substrate according to claim 1, further comprising:
a plurality of land electrodes on the laminate substrate; wherein
a thickness of the plurality of land electrodes is smaller than the thickness of the first signal line.

11. The multilayer substrate according to claim 10, further comprising:
a plurality of solder portions joined to the plurality of land electrodes on a one-to-one basis; and
an electronic component joined to the plurality of solder portions.

12. The multilayer substrate according to claim 1, wherein a thickness of a signal line farthest from the ground electrode in the thickness direction of the laminate substrate among the plurality of signal lines is larger than the thickness of the second signal line.

13. The multilayer substrate according to claim 1, wherein a material of each of the plurality of insulating layers includes a thermoplastic resin.

14. The multilayer substrate according to claim 5, further comprising a fourth ground electrode and a fifth ground electrode.

15. The multilayer substrate according to claim 14, wherein the fourth ground electrode and the fifth ground electrode are each divided into two split ground electrodes.

16. The multilayer substrate according to claim 5, wherein the laminate substrate, the RF signal line, the second ground electrode and the third ground electrode define a stripline.

17. The multilayer substrate according to claim 5, wherein the third ground electrode is divided into two split ground electrodes.

18. The multilayer substrate according to claim 11, wherein the electronic component is a connector, an IC chip, a surface-mount electronic component, a chip inductor or a chip capacitor.

19. The multilayer substrate according to claim 1, wherein a material of each of the plurality of insulating layers includes a polyimide or modified polyimide.

20. The multilayer substrate according to claim 1, further comprising a first protective film on a first main surface of the laminate substrate and a second protective film on a second main surface of the laminate substrate.
